(19) United States
(12) Patent Application Publication
(10) Pub. No.: US 2026/0033152 A1
(43) Pub. Date: Jan. 29, 2026

(54) DISPLAY PANEL AND METHOD FOR MANUFACTURING DISPLAY PANEL

(71) Applicants: Hefei Visionox Technology Co., Ltd., Hefei (CN); Visionox Technology Inc., Kunshan (CN)

(72) Inventors: Zhiwei ZHOU, Hefei (CN); Jinfang ZHANG, Hefei (CN); Yang YANG, Hefei (CN); Lu ZHANG, Kunshan (CN); Xiujian ZHU, Kunshan (CN)

(73) Assignees: Hefei Visionox Technology Co., Ltd., Hefei (CN); Visionox Technology Inc., Kunshan (CN)

(21) Appl. No.: 19/268,961

(22) Filed: Jul. 14, 2025

(30) Foreign Application Priority Data
Jul. 25, 2024 (CN) 202411010091.7

(51) Int. Cl. H10K 59/122; H10K 59/12; H10K 59/80

(52) U.S. Cl. CPC H10K 59/122; H10K 59/1201; H10K 59/873

(57) ABSTRACT

The present application provides a display panel, and a method for manufacturing a display panel. The display panel includes: a substrate; an isolation structure located on one side of the substrate, the isolation structure including spaced isolation openings and light-transmitting openings; light-emitting devices located on one side of the substrate and at least partially within the isolation openings; and a protective layer located at least partially within the light-transmitting opening, the protective layer covering a side wall of the isolation structure facing the light-transmitting opening and exposing a central position of the light-transmitting opening. In this way, the risk of the side wall of the isolation opening being further laterally etched in a subsequent manufacturing process can be reduced, and the uniformity of the display effect of the display panel can be improved.

### CROSS-REFERENCE TO RELATED APPLICATIONS

The present application claims priority to Chinese Patent Application No. 202411010091.7, filed on Jul. 25, 2024 and entitled “DISPLAY PANEL AND METHOD FOR MANUFACTURING DISPLAY PANEL AND ELECTRONIC DEVICES”, the disclosure of which is incorporated herein by reference in its entirety.

### FIELD

The present application relates to the field of display, and in particular to a display panel and a method for manufacturing a display panel.

### BACKGROUND

Organic light-emitting diodes (OLEDs) and flat panel display devices based on technologies such as light-emitting diodes (LEDs) have been widely applied to various consumer electronics such as mobile phones, televisions, notebook computers and desktop computers and predominate in display devices thanks to their advantages such as high image quality, energy efficiency, slim design and a wide range of applications.

However, the process performance of conventional OLED display products needs to be improved.

### SUMMARY

In order to overcome the above-mentioned disadvantages of the prior art, an objective of the present application is to provide a display panel, including:
a substrate;
an isolation structure located on one side of the substrate, the isolation structure including a plurality of spaced isolation openings and light-transmitting openings;
light-emitting devices located on one side of the substrate and at least partially within the isolation openings; and
a protective layer located at least partially within the light-transmitting opening, the protective layer covering a side wall of the isolation structure facing the light-transmitting opening and exposing a central position of the light-transmitting opening.

In some embodiments, the display panel further includes:
pixel encapsulation units located on a side of the light-emitting devices away from the substrate and at least partially within the isolation openings; and at least some of the pixel encapsulation units are disposed in the same layer as the protective layer.

A further objective of the present application is to provide a display panel. The display panel includes:
a substrate;
an isolation structure located on one side of the substrate, the isolation structure including a plurality of spaced isolation openings and light-transmitting openings;
light-emitting devices located on one side of the substrate and within the isolation openings; and
pixel encapsulation units located on a side of the light-emitting devices away from the substrate and at least partially within the isolation openings;
where the isolation opening includes a first isolation opening, the pixel encapsulation unit includes a first pixel encapsulation unit located at least partially within the first isolation opening, the first pixel encapsulation unit extends to a side wall covering the light-transmitting opening adjacent to the first isolation opening, and the side wall of the light-transmitting opening is the side of the isolation structure facing the light-transmitting opening.

A further objective of the present application is to provide a method for manufacturing a display panel, the method including:
providing a substrate;
forming an isolation structure on one side of the substrate, the isolation structure including a plurality of spaced isolation openings and light-transmitting openings; and
forming a protective layer located at least partially within the light-transmitting opening, the protective layer covering a side wall of the isolation structure facing the light-transmitting opening and exposing a central position of the light-transmitting opening.

In some embodiments, the step of forming a protective layer located at least partially within the light-transmitting opening, includes:
forming a light-emitting device and a pixel encapsulation unit at least partially within the isolation opening and stacked in a direction away from the substrate, and forming a protective layer at least partially within the light-transmitting opening.

A further objective of the present application is to provide an electronic device, the electronic device including the display panel provided in the present application, or the electronic device including a display panel made by a method for manufacturing the display panel provided in the present application.

The present application has the following beneficial effects with respect to the prior art.

The present application provides a display panel, a method for manufacturing the display panel, and an electronic device. By providing a protective layer to cover a side wall of an isolation structure facing a light-transmitting opening, the risk of the side wall of the isolation opening being further laterally etched in a subsequent manufacturing process can be reduced, and the uniformity of the display effect of the display panel can be improved.

### BRIEF DESCRIPTION OF THE DRAWINGS

In order to illustrate the embodiments of the present application more clearly, the drawings required in the embodiments will be briefly introduced below. It should be understood that the following drawings only show some embodiments of the present application, and therefore should not be construed as a limitation on the scope.

FIG. 1 is a schematic cross-sectional view of a display panel;

FIG. 2 is a schematic diagram of areas of a conventional display panel;

FIG. 3 is a first schematic diagram of isolation openings and light-transmitting openings of a conventional display panel;

FIG. 4 is a second schematic diagram of isolation openings and light-transmitting openings of a conventional display panel;

FIG. 5 is a first schematic cross-sectional view of a display panel according to an embodiment of the present application;

FIG. 6 is a first schematic diagram of isolation openings and light-transmitting openings of a display panel according to an embodiment of the present application;

FIG. 7 is a second schematic cross-sectional view of a display panel according to an embodiment of the present application;

FIG. 8 is a second schematic diagram of isolation openings and light-transmitting openings of a display panel according to an embodiment of the present application;

FIG. 9 is a first schematic diagram of an isolation structure according to an embodiment of the present application;

FIG. 10 is a second schematic diagram of an isolation structure according to an embodiment of the present application;

FIG. 11 is a third schematic cross-sectional view of a display panel according to an embodiment of the present application;

FIG. 12 is a fourth schematic cross-sectional view of a display panel according to an embodiment of the present application;

FIG. 13 is a schematic diagram of a protective layer according to an embodiment of the present application;

FIG. 14 is a fifth schematic cross-sectional view of a display panel according to an embodiment of the present application;

FIG. 15 is a schematic flowchart of a method for manufacturing a display panel according to an embodiment of the present application;

FIG. 16 is a first schematic diagram of a process for manufacturing a display panel according to an embodiment of the present application; and

FIG. 17 is a second schematic diagram of a process for manufacturing a display panel according to an embodiment of the present application.

List of reference signs: 111—Substrate; 112—Array functional layer; 120—First electrode; 130—Pixel defining layer; 140—Isolation structure; 141—Support portion; 142—Shielding portion; 143—Receiving portion; 150—Light-emitting unit; 154—Redundant light-emitting layer; 160—Second electrode; 164—Redundant electrode layer; 170—Pixel encapsulation unit; 171—First pixel encapsulation unit; 172—Second pixel encapsulation unit; 173—Third pixel encapsulation unit; 174—Protective layer; 1741—First portion; 1742—Second portion; 1742—Third portion; 180—First encapsulation layer; 190—Second encapsulation layer; 700—Etching barrier material; 800—Light-emitting device; 801—First light-emitting device; 802—Second light-emitting device; 803—Third light-emitting device; 804—Redundant light-emitting device layer; 910—Isolation opening; 911—First isolation opening; 912—Second isolation opening; 913—Third isolation opening; 920—Light-transmitting opening; AA1—First active area; AA2—Second active area; SA11—First pixel undercut length; SA12—Second pixel undercut length; SA21—Aperture area undercut length; 600—Gap.

### DETAILED DESCRIPTION OF THE EMBODIMENTS

In order to make the embodiments of the present application clearer, the embodiments of the present application will be described clearly and completely below with reference to the accompanying drawings in the embodiments of the present application. Apparently, the embodiments described are some of, rather than all of, the embodiments of the present application. In general, assemblies of the embodiments of the present application described and shown in the accompanying drawings herein can be arranged and designed in various configurations.

It should be noted that different features in the embodiments of the present application may be combined with each other without conflicts.

In some display panels, an isolation structure having an undercut structure is provided to disconnect an organic light-emitting material layer between different pixel openings when the organic light-emitting material layer is formed by evaporation, and organic light-emitting material layers of different colors can be formed in the different pixel openings by etching after full-layer evaporation. Patent applications PCT/CN 2023/134518, 202310759370.2, 202310740412.8, 202310707209.0, and 202311346196.5 describe related solutions for an isolation structure, the contents of which are incorporated herein by reference.

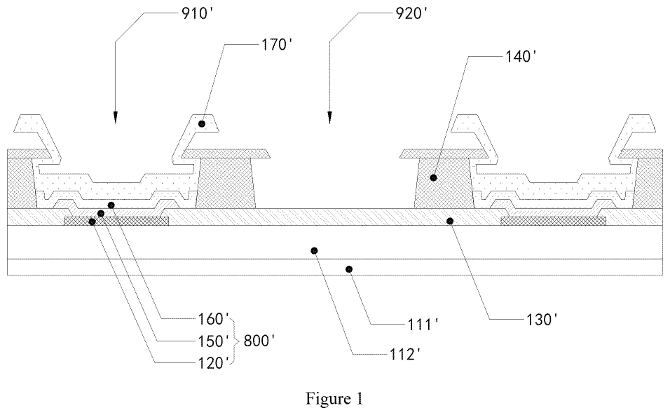

Referring to FIG. 1, in such a display panel, when the display panel is required to have a display function while also having a certain light transmittance to set up under-screen optical devices (e.g., an under-screen light sensor, an under-screen camera, an under-screen optical fingerprint sensor, etc.), isolation openings 910′ for receiving light-emitting devices 800′ are required to be formed in an isolation structure 140′, and light-transmitting openings 920′ are also formed in the isolation structure.

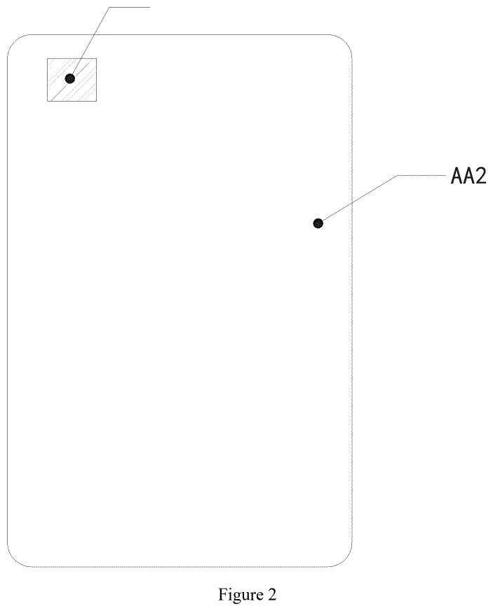

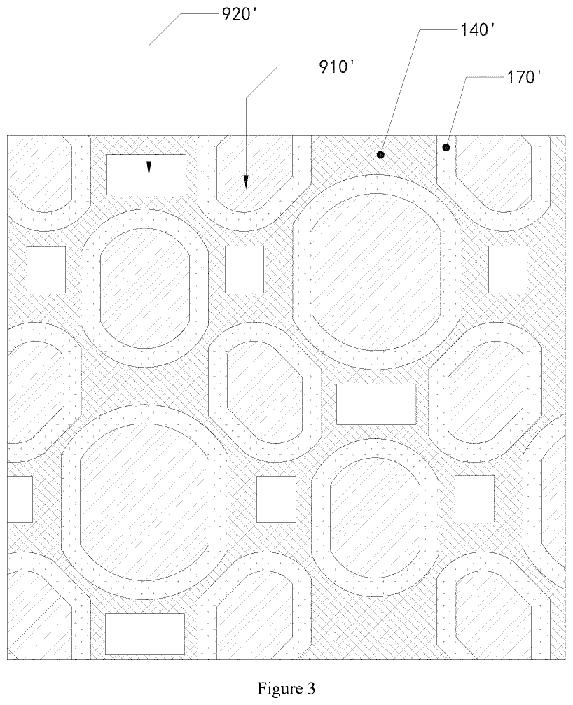

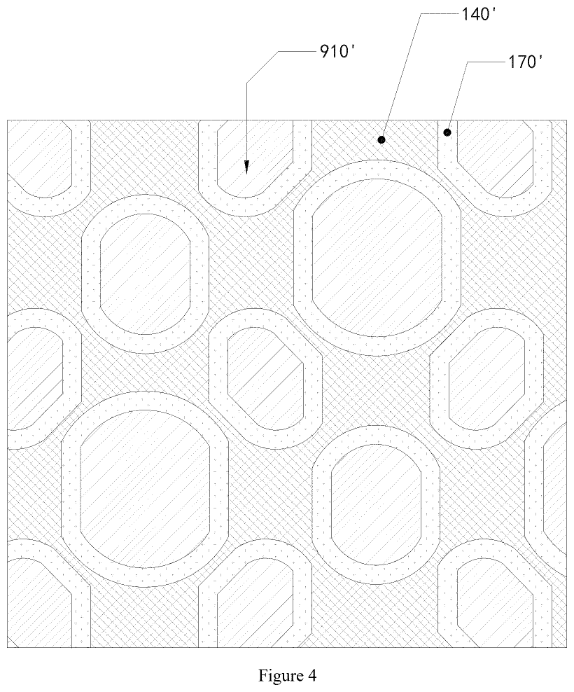

The inventor has found through research that an area where the light-transmitting opening 920′ is required is generally not too large, for example, see FIG. 2, such a display panel typically includes a first active area AA1 (e.g., a light-transmitting active area) and a second active area AA2 (e.g., a normal active area) surrounding the first active area AA1. The first active area AA1 is provided with isolation openings 910′ and light-transmitting openings 920′ (as shown in FIG. 3), and the second active area AA2 is provided with only isolation openings 910′ (as shown in FIG. 4).

Since the organic light-emitting material layer needs to be evaporated and etched several times in the process of manufacturing the display panel, in the etching process of the organic light-emitting material layer of the light-emitting device 800′ formed earlier, a side wall of the isolation structure 140′ corresponding to the isolation opening 910′ of the light-emitting device 800′ formed later may be affected by etching, i.e., being further laterally etched.

For example, during the etching of the organic light-emitting material layer of the light-emitting device 800′ formed earlier, in the first active area AA1, the light-transmitting opening 920′ and the isolation structure 140′ corresponding to the isolation opening 910′ of the light-emitting device 800′ formed later are both affected by lateral etching; while in the second active area AA2, only the isolation opening 910′ of the light-emitting device 800′ formed later is affected by the lateral etching, resulting in a difference in the density of the openings in the first active area AA1 and the second active area AA2 that are affected by the lateral etching, and a different rate of consumption of an etching solution. Side graduations of the isolation openings 910′ in the first active area AA1 and the second active area AA2 are different, resulting in a different overlap effect between electrodes of the subsequent light-emitting device 800′ and the isolation structure 140′, which affects the uniformity of the display effect.

In view of this, this embodiment provides a solution by which the uniformity of the display effect of the display panel can be improved, and the solution provided in this embodiment will be elaborated below.

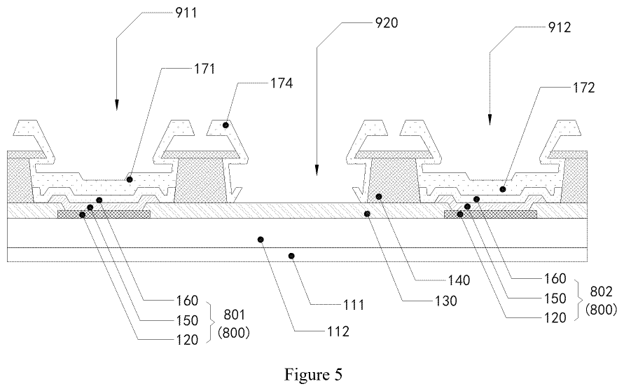

Referring to FIG. 5, this embodiment provides a display panel. The display panel may include a substrate 111, an isolation structure 140, light-emitting devices 800 and a protective layer 174.

In this embodiment, a material of the substrate 111 may include a rigid material, such as glass. In some embodiments, the material of the substrate 111 may include a flexible material, such as polyimide (Pi).

In some embodiments, an array functional layer 112 may also be provided on one side of the substrate 111, and the array functional layer 112 may include a plurality of film layer structures, such as a buffer layer, an active layer, a plurality of conductive layers, a plurality of insulation layers, a planarization layer, etc. The plurality of film layer structures of the array functional layer 112 may form a plurality of thin film transistors (TFTs) at different locations, and the thin film transistors cooperate with each other to form a plurality of pixel drive units or drive circuits.

The isolation structure 140 is located on one side of the substrate 111, for example, the isolation structure 140 may be located on a side of the array functional layer 112 away from the substrate 111. The isolation structure 140 includes a plurality of spaced isolation openings 910 and light-transmitting openings 920.

In some embodiments, referring again to FIG. 2, this embodiment provides a display panel that may include a first active area AA1 and a second active area AA2, where isolation openings 910 are located in the first active area AA1 and the second active area AA2, and light-transmitting openings 920 are located in the first active area AA1. In some embodiments, the second active area AA2 at least partially surrounds the first active area AA1.

In some embodiments, referring again to FIG. 5, the display panel further includes a pixel defining layer 130 between the isolation structure 140 and the substrate 111, the pixel defining layer 130 including pixel openings, the isolation structure 140 being located on a side of the pixel defining layer 130 away from the substrate 111, and orthographic projections of the pixel openings on the substrate 111 are located within orthographic projections of the isolation openings 910 on the substrate 111.

In this embodiment, the light-transmitting opening 920 exposes the pixel defining layer 130, and the pixel defining layer 130 may have light transmittance. In some embodiments, the array functional layer 112 may have a light-transmitting area, and an orthographic projection of the light-transmitting area on the substrate 111 may at least partially coincide with an orthographic projection of the light-transmitting opening 920 on the substrate 111. In this way, ambient light may pass through the light-transmitting opening 920, then through the pixel defining layer 130, and then through the light-transmitting area of the array functional layer 112 and the substrate 111 to be irradiated beneath the display panel.

The light-emitting devices 800 are located on one side of the substrate 111 and at least partially within the isolation openings 910. That is, in this embodiment, a light-emitting device is provided in the isolation opening 910, and no light-emitting device is provided in the isolation opening 920.

In some embodiments, each light-emitting device 800 includes a first electrode 120, a light-emitting unit 150 and a second electrode 160 that are stacked in a direction away from the substrate 111. The isolation structure 140 is electrically conductive, and the second electrode 160 is electrically connected to the isolation structure 140.

In some embodiments, the first electrode 120 may be connected to a pixel drive circuit in the array substrate, the second electrode 160 may be connected to a common voltage supply circuit through the isolation structure 140, and when there is a potential difference between the first electrode 120 and the second electrode 160, the light-emitting unit 150, which is located between the first electrode 120 and the second electrode 160, is driven to emit light.

The protective layer 174 is located at least partially within the light-transmitting opening 920, see FIG. 6, and the protective layer 174 covers a side wall of the isolation structure 140 facing the light-transmitting opening 920 and expose the central position of the light-transmitting opening 920. In some embodiments, at least part of the protective layer 174 extends along the side wall of the isolation structure 140 toward the light-transmitting opening 920 to the side of the isolation structure 140 away from the substrate 111.

Based on the above design, in the display panel provided in this embodiment, the protective layer 174 is provided to cover the side walls of the isolation structure 140 facing the light-transmitting openings 920, and in a subsequent manufacturing process, the protective layer 174 may protect the side walls of the isolation structure 140 at the light-transmitting opening 920 from being further laterally etched, to improve the uniformity of the corresponding lateral etching level of the isolation openings 910 at different locations, thus improving the uniformity of the display effect of the display panel.

In some embodiments, the display panel may also include a pixel encapsulation unit 170, the pixel encapsulation unit 170 being located on a side of the light-emitting device 800 away from the substrate 111 and at least partially within the isolation opening 910. The pixel encapsulation unit 170 may extend from within the isolation opening 910 to the side of the isolation structure 140 away from the substrate 111.

In some embodiments, a gap is provided between pixel encapsulation units 170 corresponding to at least some adjacent isolation openings 910, and the gap is located on the side of the isolation structure 140 away from the substrate 111.

In this case, at least part of the pixel encapsulation unit 170 is disposed in the same layer as the protective layer 174. For example, at least part of the pixel encapsulation unit 170 and the protective layer 174 are formed in the same manufacturing process.

In this way, at least part of the pixel encapsulation unit 170 is manufactured at the same time as the protective layer 174, which reduces the manufacturing process and lowers the manufacturing cost.

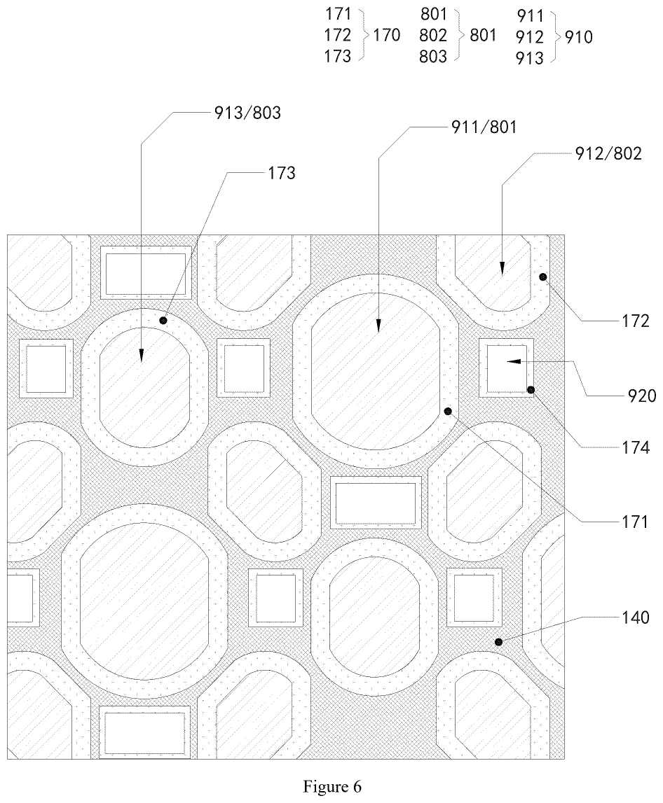

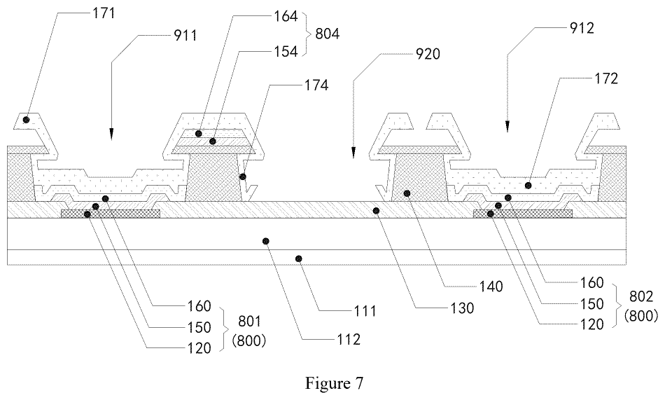

In some embodiments, with reference to FIG. 7, the isolation opening 910 includes a first isolation opening 911 and a second isolation opening 912 that are adjacent to the light-transmitting opening 920.

The light-emitting device 800 includes a first light-emitting device 801 located in the first isolation opening 911 and a second light-emitting device 802 located in the second isolation opening 912, the first light-emitting device 801 and the second light-emitting device 802 having different light-emitting colors.

The pixel encapsulation unit 170 includes a first pixel encapsulation unit 171 located at least partially within the first isolation opening 911 and a second pixel encapsulation unit 172 located at least partially within the second isolation opening 912. The first pixel encapsulation unit 171 is located on a side of the first light-emitting device 801 away from the substrate 111, and the second pixel encapsulation unit 172 is located on a side of the second light-emitting device 802 away from the substrate 111.

The first pixel encapsulation unit 171 is connected to the protective layer 174 on the side of the isolation structure 140 between the first isolation opening 911 and the light-transmitting opening 920 that is away from the substrate 111. The second pixel encapsulation unit 172 is disconnected from the protective layer 174 on the side of the isolation structure 140 between the second isolation opening 912 and the light-transmitting opening 920 that is away from the substrate 111.

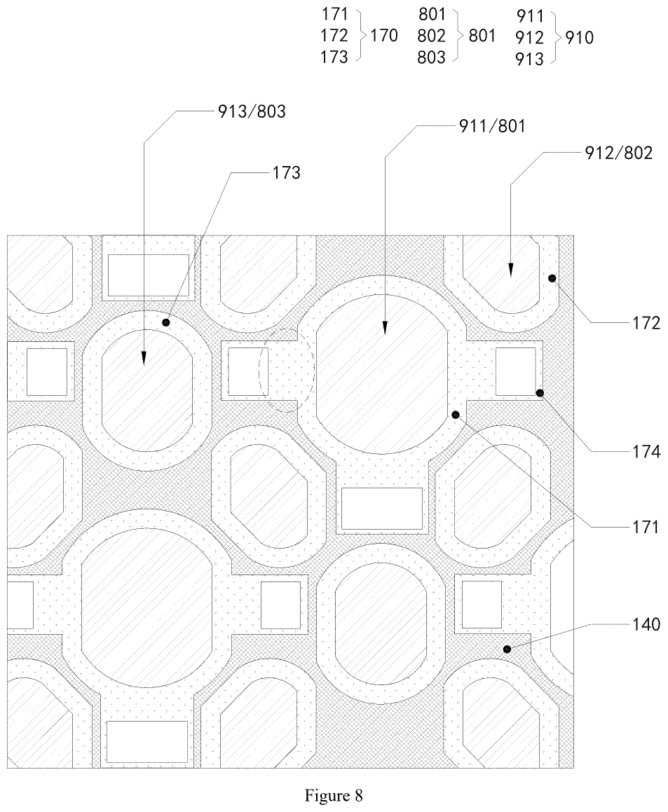

For example, referring to FIG. 8, the protective layer 174 and the first pixel encapsulation unit 171 may be made in the same step, and the protective layer 174 and the first pixel encapsulation unit 171 may be continuous (as shown in FIG. 8 at an elliptical dashed box). In contrast, the second pixel encapsulation unit 172 is made in another step, and the second pixel encapsulation unit 172 is disconnected from the protective layer 174.

In some embodiments, the isolation opening 910 further includes a third isolation opening 913 adjacent to the light-transmitting opening 920. The light-emitting device 800 further includes a third light-emitting device 803 located in the third isolation opening 913, the third light-emitting device 803 having a light-emitting color different from the light-emitting color of the first light-emitting device 801 and the second light-emitting device 802. The pixel encapsulation unit 170 includes a third pixel encapsulation unit 173 located at least partially within the third isolation opening 913.

The third pixel encapsulation unit 173 is disconnected from the protective layer 174 on the side of the isolation structure 140 between the third isolation opening 913 and the light-transmitting opening 920 that is away from the substrate 111.

For example, the protective layer 174 and the first pixel encapsulation unit 171 may be made in the same step, and the protective layer 174 and the first pixel encapsulation unit 171 may be continuous. In contrast, the third pixel encapsulation unit 173 is made in another step, and the third pixel encapsulation unit 173 is disconnected from the protective layer 174.

In some embodiments, in this embodiment, light-emitting colors of the first light-emitting device 801, the second light-emitting device 802 and the third light-emitting device 803 may be one of blue, green and red respectively.

In some embodiments, referring again to FIG. 7, the display panel further includes a redundant device layer 804, the redundant device layer 804 being located on a side of the isolation structure 140 between the first isolation opening 911 and the light-transmitting opening 920 that is away from the substrate 111.

In some embodiments, the redundant device layer 804 may include a redundant light-emitting layer 154 and a redundant electrode layer 164 stacked in a direction away from the substrate 111.

The light-emitting color of the redundant device layer 804 is the same as the light-emitting color of the first light-emitting device 801, and is different from the light-emitting color of the second light-emitting device 802.

It should be noted that in this embodiment, the light-emitting color of the redundant light-emitting device layer 804 is a light-emitting color that the light-emitting material included in the redundant light-emitting device layer 804 (i.e., the redundant light-emitting layer 154) can produce upon electroluminescence, and the redundant light-emitting device layer 804 does not emit light when the display panel is actually working.

The first pixel encapsulation unit 171 is connected to the protective layer 174 on the side of the redundant device layer 804 away from the substrate 111.

For example, the redundant light-emitting device layer 804 and the first light-emitting device 801 are formed in the same step, and the light-emitting color of the redundant light-emitting device layer 804 is the same as the light-emitting color of the first light-emitting device 801. In contrast, the second light-emitting device 802 is made in another step, and the light-emitting color of the second light-emitting device 802 is different from the light-emitting color of the redundant light-emitting device layer 804.

In some embodiments, the light-emitting color of the redundant device layer 804 is different from the light-emitting color of the third light-emitting device 803.

For example, the redundant light-emitting device layer 804 and the first light-emitting device 801 are formed in the same step, and the light-emitting color of the redundant light-emitting device layer 804 is the same as the light-emitting color of the first light-emitting device 801. In contrast, the third light-emitting device 803 is made in another step, and therefore, the light-emitting color of the third light-emitting device 803 is different from the light-emitting color of the redundant light-emitting device layer 804.

In some other possible implementations, the protective layer 174 is disconnected from an adjacent encapsulation unit 170 on a side of the isolation structure 140 away from the substrate 111.

Specifically, the protective layer 174 and the first pixel encapsulation unit 171 may be manufactured in the same step. In contrast, a gap may also be provided between the protective layer 174 and the first pixel encapsulation unit 171, and the gap may be located on the side of the isolation structure 140 between the light-transmitting opening 920 and the first isolation opening 911 away from the substrate 111. For example, referring again to FIGS. 5 and 6, an orthographic projection of the protective layer 174 on the substrate 111 may be annular around the light-transmitting opening 920.

The protective layer 174, the second pixel encapsulation unit 172, and the third pixel encapsulation unit 173 are formed in different manufacturing steps, and there are gaps between the protective layer 174 and the second pixel encapsulation unit 172, and between the protective layer 174 and the third pixel encapsulation unit 173, which are disconnected from each other.

In some embodiments, the first light-emitting device 801 and the first pixel encapsulation unit 171 are manufactured prior to the second light-emitting device 802 and the second pixel encapsulation unit 172. In some embodiments, the first light-emitting device 801 and the first pixel encapsulation unit 171 are manufactured prior to the third light-emitting device 803 and the third pixel encapsulation unit 173.

That is, when the first pixel encapsulation unit 171 is provided, the protective layer 174 is also provided on the side wall of the light-transmitting opening 920, and in a subsequent etching process of the first light-emitting device 801, the side wall of the light-transmitting opening 920 protected by the protective layer 174 is not further etched, to ensure environmental uniformity of the first active area AA1 and the second active area AA2, and thus ensuring uniformity of the display effect of the display panel.

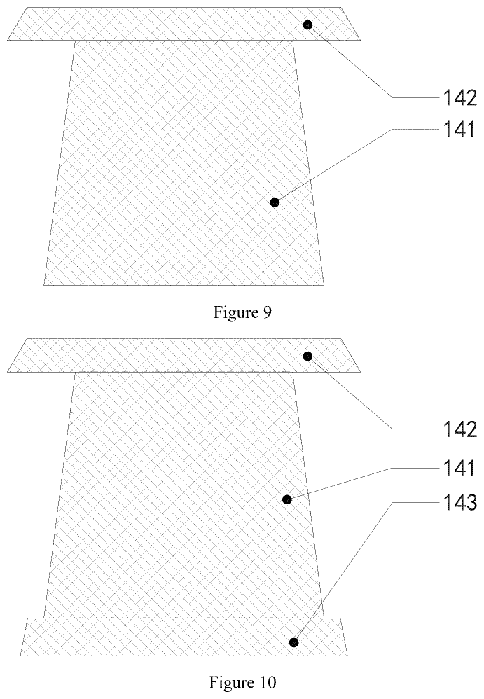

In some embodiments, with reference to FIG. 9, the isolation structure 140 includes a support portion 141 and a shielding portion 142 on a side of the support portion 141 away from the substrate 111, and an orthographic projection of the support portion 141 on the substrate 111 is located within an orthographic projection of the shielding portion 142 on the substrate 111. That is, at a position near the isolation opening 910 and near the light-transmitting opening 920, the support portion 141 is inwardly retracted compared with the shielding portion 142 to form an undercut structure.

In some embodiments, an etching resistance of the support portion 141 is weaker than an etching resistance of the shielding portion 142. For example, the same etching solution or etching gas has a greater etching rate for the support portion 141 than the etching rate for the shielding portion 142.

In some embodiments, a material of the support portion 141 includes aluminum, and/or a material of the shielding portion 142 includes titanium.

In some embodiments, with reference to FIG. 10, the isolation structure 140 further includes a receiving portion 143 between the support portion 141 and the substrate 111.

In some embodiments, an orthographic projection of the support portion 141 on the substrate 111 is located within an orthographic projection of the receiving portion 143 on the substrate 111.

In some embodiments, an orthographic projection of the receiving portion 143 on the substrate 111 is located within an orthographic projection of the shielding portion 142 on the substrate 111.

In some embodiments, a material of the receiving portion 143 includes molybdenum.

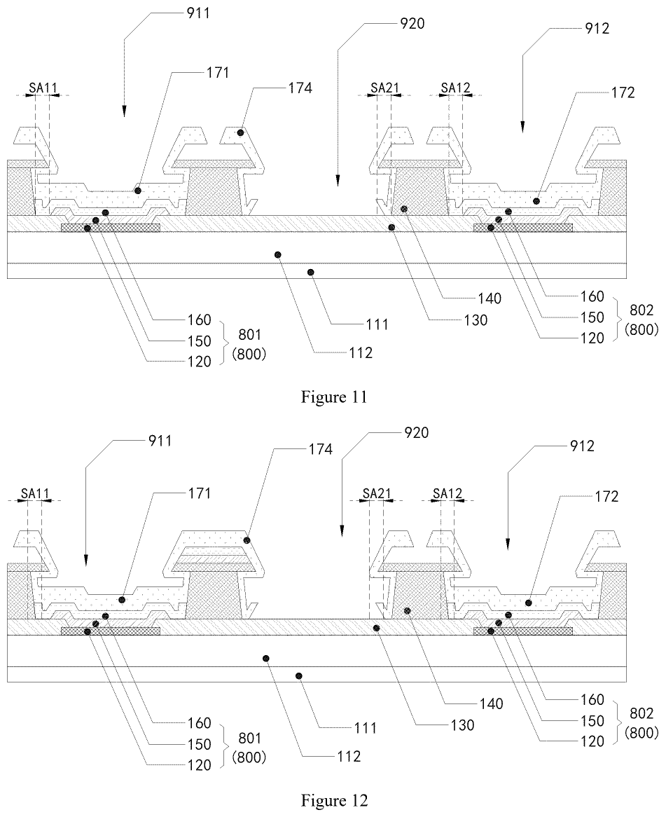

In some embodiments, referring to FIGS. 11 and 12, the isolation opening 910 includes a first isolation opening 911, and a difference between an aperture area undercut length SA21 corresponding to the light-transmitting opening 920 and a first pixel undercut length SA11 corresponding to the first isolation opening 911 adjacent to the light-transmitting opening 920 is less than 0.1 micron.

The first pixel undercut length SA11 is a distance between an orthographic projection of an end of the shielding portion 142 near the first isolation opening 911 on the substrate 111 to an orthographic projection of an end of the support portion 141 near the first isolation opening 911 on the substrate 111, and the aperture area undercut length SA21 is a distance between an orthographic projection of an end of the shielding portion 142 near the light-transmitting opening 920 on the substrate 111 and an orthographic projection of an end of the support portion 141 near the light-transmitting opening 920 on the substrate 111.

In some embodiments, the first isolation opening 911 and the light-transmitting opening 920 may be etched in the same step in this embodiment. For example, after the entire layer of the covered isolation structure 140 is provided, the first isolation opening 911, the second isolation opening 912, the third isolation opening 913 and the light-transmitting opening 920 may be formed in the same etching step, and after this step, the undercut length corresponding to the adjacent isolation opening 910 and the light-transmitting opening 920 may be approximately the same.

Then, in the manufacturing process of the first light-emitting device 801, the first pixel encapsulation unit 171 and the protective layer 174 are formed simultaneously in the first isolation opening 911 and the light-transmitting opening 920, respectively, and in subsequent other etching processes, the side walls of the isolation structure 140 corresponding to the first isolation opening 911 and the light-transmitting opening 920 are no longer affected by lateral etching. Therefore, the aperture area undercut length SA21 corresponding to the light-transmitting opening 920 and the first pixel undercut length SA1l corresponding to the first isolation opening 911 adjacent to the light-transmitting opening 920 are substantially equal or the difference between the two is less than 0.1 micron.

In some embodiments, the aperture area undercut length SA21 corresponding to the light-transmitting opening 920 is less than the second pixel undercut length SA12 corresponding to the second isolation opening 912, and the second pixel undercut length SA12 is a distance between an orthographic projection of an end of the shielding portion 142 near the second isolation opening 912 on the substrate 111 and an orthographic projection of an end of the support portion 141 near the second isolation opening 912 on the substrate 111.

In some embodiments, the aperture area undercut length SA21 corresponding to the light-transmitting opening 920 is less than a third pixel undercut length (not shown) corresponding to the third isolation opening 913, and the third pixel undercut length is a distance between an orthographic projection of an end of the shielding portion 142 near the third isolation opening 913 on the substrate 111 and an orthographic projection of an end of the support portion 141 near the third isolation opening 913 on the substrate 111.

Specifically, since the second light-emitting device 802 and the third light-emitting device 803 are manufactured later than the first light-emitting device 801, the second isolation opening 912 and the third isolation opening 913 are not protected by the pixel encapsulation unit 170 in the etching operation for the first light-emitting device 801, and in this case, the isolation structure 140 corresponding to the second isolation openings 912 and the third isolation openings 913 may be further laterally etched, thus the aperture area undercut length SA21 corresponding to the light-transmitting opening 920 is less than the second pixel undercut length SA12 corresponding to the second isolation opening 912 adjacent thereto and the third pixel undercut length corresponding to the third isolation opening 913.

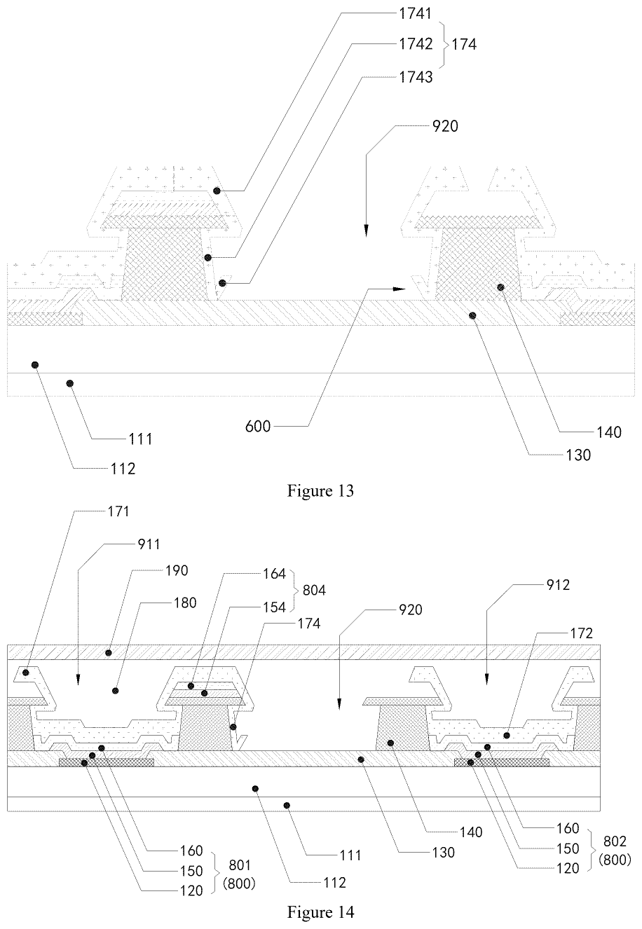

In some embodiments, referring to FIG. 13, the protective layer 174 includes a first portion 1741, a second portion 1742 and a third portion 1742 that are interconnected, where the first portion 1741 is located on a side of the isolation structure 140 away from the pixel defining layer 130, the second portion 1742 covers a side wall of the isolation structure 140 facing the light-transmitting opening 920, and the third portion 1742 extends from an end of the side wall of the isolation structure 140 near the pixel defining layer 130 to the central position of the light-transmitting opening 920, a gap 600 being provided between the third portion 1742 and the pixel defining layer 130. For example, the third portion 1742 may be tilted to form an angle with the side of the pixel defining layer 130 away from the substrate 111.

In some embodiments, with reference to FIG. 14, the display panel further includes a first encapsulation layer 180 and a second encapsulation layer 190 on a side of the pixel encapsulation unit 170, the protective layer 174 and the isolation structure 140 away from the substrate 111.

In some embodiments, a material of each of the pixel encapsulation unit 170, the protective layer 174 and the second encapsulation layer 190 includes an inorganic material. And/or a material of the first encapsulation layer 180 includes an organic material.

For example, the pixel encapsulation unit 170, the protective layer 174 and the second encapsulation layer 190 may be formed by means of chemical vapor deposition (CVD), and the first encapsulation layer 180 may be formed by means of ink-jet printing (IJP).

In some embodiments, the display panel provided in this embodiment may further include film layer structures such as an optical film (e.g., a polarizer), a transparent adhesive layer (e.g., an optical adhesive layer) and a cover plate that are located on the side of the second encapsulation layer 190 away from the substrate 111.

This embodiment further provides a display panel, where the display panel includes a substrate 111, an isolation structure 140, light-emitting devices 800, and pixel encapsulation units 170.

The isolation structure 140 is located on one side of the substrate 111, for example, the isolation structure 140 may be located on a side of the array functional layer 112 away from the substrate 111. The isolation structure 140 includes a plurality of spaced isolation openings 910 and light-transmitting openings 920.

The light-emitting devices 800 are located on one side of the substrate 111 and at least partially within the isolation openings 910.

The pixel encapsulation unit 170 is located on the side of the light-emitting device 800 away from the substrate 111 and at least partially within the isolation opening 910. The pixel encapsulation unit 170 may extend from within the isolation opening 910 to the side of the isolation structure 140 away from the substrate 111.

The isolation opening 910 includes a first isolation opening 911, the pixel encapsulation unit 170 includes a first pixel encapsulation unit 171 located at least partially within the first isolation opening 911, the first pixel encapsulation unit 171 extends to a side wall covering the light-transmitting opening 920 adjacent to the first isolation opening 911, and the side wall of the light-transmitting opening 920 is the side of the isolation structure 140 facing the light-transmitting opening 920.

That is, the first encapsulation unit corresponding to the first isolation opening 911 extends to cover a side wall of at least one light-transmitting opening 920 adjacent to the first isolation opening 911, in addition to covering the first isolation opening 911.

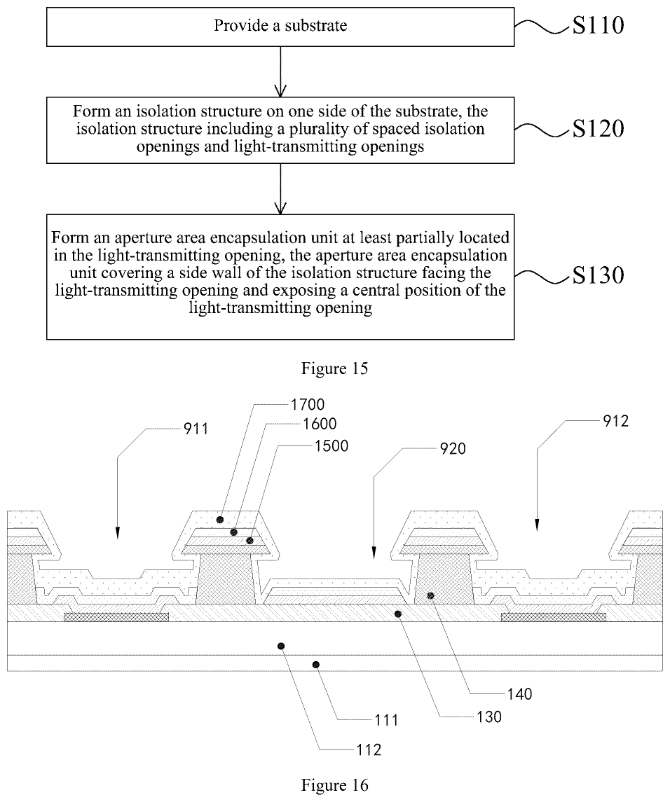

This embodiment provides a method for manufacturing a display panel. Referring to FIG. 15, the method may include the following steps.

In step S110, a substrate 111 is provided.

In step S120, an isolation structure 140 is formed on one side of the substrate 111, the isolation structure 140 including a plurality of spaced isolation openings 910 and light-transmitting openings 920.

In step S130, a light-emitting device 800 and a pixel encapsulation unit 170 are formed at least partially located in the isolation opening 910 and stacked in a direction away from the substrate 111, a protective layer 174 is formed at least partially located in the light-transmitting opening 920, and the protective layer 174 covers a side wall of the isolation structure 140 facing the light-transmitting opening 920, and exposes the central position of the light-transmitting opening 920.

In some embodiments, the isolation opening 910 includes a first isolation opening 911 and a second isolation opening 912, the light-emitting device 800 includes a first light-emitting device 801 and a second light-emitting device 802, and the pixel encapsulation unit 170 includes a first pixel encapsulation unit 171 and a second pixel encapsulation unit 172.

Specifically, the following sub-steps may be included in step S130.

In step S131, a first light-emitting unit 150 and the first pixel encapsulation unit 171 at least partially located in the first isolation opening 911 are formed, and the protective layer 174 is formed.

In step S132, a second light-emitting unit 150 and the second pixel encapsulation unit 172 are formed at least partially within the second isolation opening 912.

That is, in this embodiment, the first light-emitting unit 150, the first pixel encapsulation unit 171, and the protective layer 174 are manufactured before the second light-emitting unit 150 and the second pixel encapsulation unit 172.

In some embodiments, the isolation opening 910 further includes a third isolation opening 913, the light-emitting device 800 further includes a third light-emitting device 803, and the pixel encapsulation unit 170 further includes a third pixel encapsulation unit 173. Step S132 may be followed by step S133.

In step S133, a third light-emitting unit 150 and a third pixel encapsulation unit 173 are formed at least partially within the third isolation opening 913.

That is, in this embodiment, the first light-emitting unit 150, the first pixel encapsulation unit 171, and the protective layer 174 are manufactured before the third light-emitting unit 150 and the third pixel encapsulation unit 173.

In some embodiments, in step S131, an entire layer of the covered light-emitting functional layer and an encapsulation material layer 1600 may be first provided from the side of the isolation structure 140 away from the substrate 111.

For example, see FIG. 16, the light-emitting functional layer may include a light-emitting material layer 1500 and an electrode material layer 1600 which are stacked.

Next, an etching barrier material 700 covering edges of the first isolation opening 911 and the light-transmitting opening 920 is provided. The etching barrier material 700 may include a photoresist.

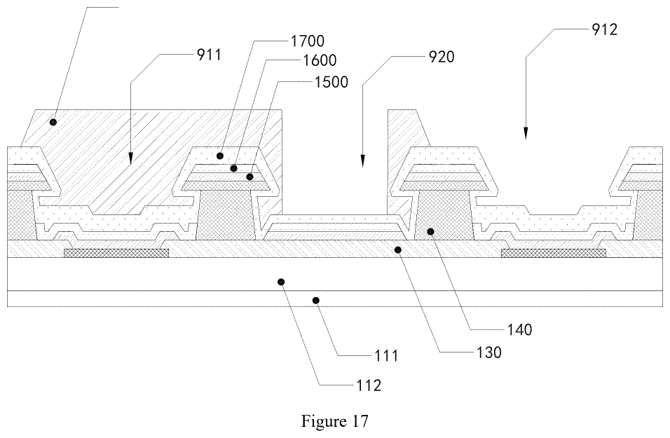

Referring to FIG. 17, the etching barrier material may cover the first isolation opening 911 and cover the edge of the light-transmitting opening 920, particularly covering the side wall of the light-transmitting opening 920.

Then, the encapsulation material layer 1600 and the light-emitting functional layer are etched under the protection of the etching barrier material 700 to form the first light-emitting device 801, the first pixel encapsulation unit 171 and the protective layer 174, to form a structure as shown in FIG. 7.

When the encapsulation material layer 1600 and the light-emitting functional layer located above the isolation structure 140 between the first isolation opening 911 and the light-transmitting opening 920 are also covered by the etching barrier material, the light-emitting functional layer at this location is not etched, to form the redundant light-emitting device layer 804.

When the encapsulation material layer 1600 and the light-emitting functional layer located above the isolation structure 140 between the first isolation opening 911 and the light-transmitting opening 920 are not covered by the etching barrier material, the encapsulation material layer 1600 and the light-emitting functional layer located at this location are also etched, and the first pixel encapsulation unit 171 and the protective layer 174 are disconnected, forming a structure shown in FIG. 5.

The present application also provides an electronic device, including a display panel provided in the present application, or a display panel made by a method for manufacturing the display panel provided in the present application. The electronic device may include a device having a display function, e.g., a mobile phone, a tablet, a smart wearable device, a TV, a laptop, a display, etc.

In view of the above, the present application provides a display panel, a method for manufacturing the display panel, and an electronic device. By providing a protective layer to cover a side wall of an isolation structure facing a light-transmitting opening, the risk of the side wall of the isolation opening being further laterally etched in a subsequent manufacturing process can be reduced, and the uniformity of the display effect of the display panel can be improved.

The above embodiments may be randomly combined. To make the description concise, not all possible combinations of the above embodiments are described. However, the combinations of these embodiments shall be considered as falling within the scope recorded in this specification provided that no conflict exists.

The above embodiments merely represent several implementations of the present disclosure, giving specifics and details thereof, but should not be understood as limiting the scope of the present disclosure thereby. Therefore, the scope of protection of the present disclosure shall be in accordance with the appended claims.

What is claimed is:

1. A display panel, comprising:
a substrate;
an isolation structure located on one side of the substrate, the isolation structure comprising a plurality of spaced isolation openings and a plurality of light-transmitting openings;
a plurality of light-emitting devices located on one side of the substrate and at least partially within the isolation openings; and
a protective layer located at least partially within the light-transmitting opening, the protective layer covering a side wall of the isolation structure facing the light-transmitting opening and exposing a central position of the light-transmitting opening.

2. The display panel according to claim 1, the display panel further comprising: pixel encapsulation units located on a side of the light-emitting devices away from the substrate and at least partially within the isolation openings; and at least some of the pixel encapsulation units are disposed in the same layer as the protective layer.

3. The display panel according to claim 2, wherein the isolation openings comprise a first isolation opening and a second isolation opening adjacent to one of the light-transmitting openings;
the light-emitting devices comprise a first light-emitting device located in the first isolation opening and a second light-emitting device located in the second isolation opening, the first light-emitting device and the second light-emitting device having different light-emitting colors;
the pixel encapsulation units comprise a first pixel encapsulation unit located at least partially within the first isolation opening and a second pixel encapsulation unit located at least partially within the second isolation opening;
the first pixel encapsulation unit is connected to the protective layer on a side of the isolation structure between the first isolation opening and the one of the light-transmitting opening away from the substrate; and
the second pixel encapsulation unit is disconnected from the protective layer on a side of the isolation structure between the second isolation opening and the one of the light-transmitting opening away from the substrate.

4. The display panel according to claim 3, wherein the isolation openings further comprise a third isolation opening adjacent to one of the light-transmitting openings; the light-emitting devices further comprise a third light-emitting device located within the third isolation opening, the light-emitting color of the third light-emitting device being different from the light-emitting colors of the first light-emitting device and the second light-emitting device; the pixel encapsulation units comprise a third pixel encapsulation unit located at least partially within the third isolation opening; and
the third pixel encapsulation unit is disconnected from the protective layer on the side of the isolation structure between the third isolation opening and the light-transmitting opening away from the substrate.

5. The display panel according to claim 3, wherein the display panel further comprises a redundant device layer on the side of the isolation structure between the first isolation opening and the light-transmitting opening away from the substrate;
the light-emitting color of the redundant device layer is the same as the light-emitting color of the first light-emitting device and different from the light-emitting color of the second light-emitting device; and
the first pixel encapsulation unit is connected to the protective layer on a side of the redundant device layer away from the substrate.

6. The display panel according to claim 2, wherein the protective layer and the encapsulation unit adjacent to the protective layer are disconnected on a side of the isolation structure away from the substrate.

7. The display panel according to claim 1, wherein the isolation structure comprises a support portion and a shielding portion on a side of the support portion away from the substrate, and an orthographic projection of the support portion on the substrate is located within an orthographic projection of the shielding portion on the substrate;
an etching resistance of the support portion is weaker than an etching resistance of the shielding portion;
a material of the support portion comprises aluminum, and a material of the shielding portion comprises titanium;
the isolation structure further comprises a receiving portion between the support portion and the substrate;
the orthographic projection of the support portion on the substrate is located within an orthographic projection of the receiving portion on the substrate;
the orthographic projection of the receiving portion on the substrate is located within the orthographic projection of the shielding portion on the substrate; and
a material of the receiving portion comprises molybdenum.

8. The display panel according to claim 7, wherein the isolation openings comprise a first isolation opening, and a difference between an aperture area undercut length corresponding to the light-transmitting opening and a first pixel undercut length corresponding to the first isolation opening adjacent to the light-transmitting opening is less than 0.1 microns; and
the first pixel undercut length is a distance between an orthographic projection of an end of the shielding portion near the first isolation opening on the substrate and an orthographic projection of an end of the support portion near the first isolation opening on the substrate, and the aperture area undercut length is a distance between an orthographic projection of an end of the shielding portion near the light-transmitting opening on the substrate and an orthographic projection of an end of the support portion near the light-transmitting opening on the substrate.

9. The display panel according to claim 8, wherein the isolation openings further comprise a second isolation opening, the light-emitting devices comprise a first light-emitting device located within the first isolation opening and a second light-emitting device located within the second isolation opening, and the first light-emitting device and the second light-emitting device have different light-emitting colors; and
the aperture area undercut length corresponding to the light-transmitting opening is less than a second pixel undercut length corresponding to the second isolation opening, and the second pixel undercut length is a distance between an orthographic projection of an end of the shielding portion near the second isolation opening on the substrate and an orthographic projection of an end of the support portion near the second isolation opening on the substrate.

10. The display panel according to claim 9, wherein the isolation openings further comprise a third isolation opening, the light-emitting devices further comprise a third light-emitting device located within the third isolation opening, the light-emitting color of the third light-emitting device being different from the light-emitting colors of the first light-emitting device and the second light-emitting device; and
the aperture area undercut length corresponding to the light-transmitting opening is less than a third pixel undercut length corresponding to the third isolation opening, and the third pixel undercut length is a distance between an orthographic projection of an end of the shielding portion near the third isolation opening on the substrate and an orthographic projection of an end of the support portion near the third isolation opening on the substrate.

11. The display panel according to claim 1, wherein the display panel further comprises a pixel defining layer located between the isolation structure and the substrate, the pixel defining layer comprising a pixel opening, the isolation structure being located on a side of the pixel defining layer away from the substrate, and an orthographic projection of the pixel opening on the substrate being located within an orthographic projection of the isolation opening on the substrate;
the light-transmitting openings expose the pixel defining layer; and
the pixel defining layer has light transmittance.

12. The display panel according to claim 11, wherein the protective layer comprises a first portion, a second portion and a third portion that are interconnected, wherein the first portion is located on a side of the isolation structure away from the pixel defining layer, the second portion covers a side wall of the isolation structure facing the light-transmitting opening, and the third portion extends from an end of the side wall of the isolation structure near the pixel defining layer to a central position of the light-transmitting opening, a gap being provided between the third portion and the pixel defining layer.

13. The display panel according to claim 1, wherein the display panel comprises a first active area and a second active area, the isolation openings are located in the first active area and the second active area, and the light-transmitting openings are located in the first active area; and
the second active area at least partially surrounds the first active area.

14. The display panel according to claim 1, wherein each of the light-emitting devices comprises a first electrode, a light-emitting unit and a second electrode which are stacked in a direction away from the substrate; and
the isolation structure is electrically conductive, and the second electrode is electrically connected to the isolation structure.

15. The display panel according to claim 2, wherein the display panel further comprises a first encapsulation layer and a second encapsulation layer on a side of the pixel encapsulation units, the protective layer and the isolation structure away from the substrate;
a material of each of the pixel encapsulation unit, the protective layer and the second encapsulation layer comprises an inorganic material; and
a material of the first encapsulation layer comprises an organic material.

16. A display panel, comprising:
a substrate;
an isolation structure located on one side of the substrate, the isolation structure comprising a plurality of spaced isolation openings and a plurality of light-transmitting openings;
a plurality of light-emitting devices located on one side of the substrate and within the isolation openings; and
pixel encapsulation units located on a side of the light-emitting devices away from the substrate and at least partially within the isolation openings;
wherein the isolation opening comprises a first isolation opening, the pixel encapsulation unit comprises a first pixel encapsulation unit located at least partially within the first isolation opening, the first pixel encapsulation unit extends to a side wall covering the light-transmitting opening adjacent to the first isolation opening, and the side wall of the light-transmitting opening is the side of the isolation structure facing the light-transmitting opening.

17. A method for manufacturing a display panel, the method comprising:
providing a substrate;
forming an isolation structure on one side of the substrate, the isolation structure comprising a plurality of spaced isolation openings and light-transmitting openings; and
forming a protective layer located at least partially within the light-transmitting opening, the protective layer covering a side wall of the isolation structure facing the light-transmitting opening and exposing a central position of the light-transmitting opening.

18. The method according to claim 17, wherein the step of forming a protective layer located at least partially within the light-transmitting opening, comprises:
forming a light-emitting device and a pixel encapsulation unit at least partially within one of the isolation opening and stacked in a direction away from the substrate, and forming a protective layer at least partially within one of the light-transmitting opening.

19. The method according to claim 18, wherein the isolation openings comprise a first isolation opening and a second isolation opening, the light-emitting devices comprise a first light-emitting device and a second light-emitting device, and the pixel encapsulation units comprise a first pixel encapsulation unit and a second pixel encapsulation unit;
the step of forming a light-emitting device and a pixel encapsulation unit at least partially within the isolation opening and stacked in a direction away from the substrate, and forming a protective layer at least partially within the light-transmitting opening, comprises:
forming a first light-emitting unit and the first pixel encapsulation unit at least partially located in the first isolation opening, and forming the protective layer; and
forming a second light-emitting unit and the second pixel encapsulation unit at least partially within the second isolation opening;
the isolation openings further comprise a third isolation opening, the light-emitting devices further comprise a third light-emitting device, and the pixel encapsulation units further comprise a third pixel encapsulation unit;
after the step of forming the first light-emitting unit and the first pixel encapsulation unit at least partially located in the first isolation opening, and forming the protective layer, the method further comprises:
forming a third light-emitting unit and a third pixel encapsulation unit at least partially within the third isolation opening.

20. The method according to claim 19, wherein the step of forming the first light-emitting unit and the first pixel encapsulation unit at least partially located in the first isolation opening, and forming the protective layer, comprises:
providing an entire layer of covered light-emitting functional layer and an encapsulation material layer from a side of the isolation structure away from the substrate;
providing an etching barrier material covering the first isolation opening and an edge of the light-transmitting opening; and
etching the encapsulation material layer and the light-emitting functional layer under the protection of the etching barrier material to form the first light-emitting device, the first pixel encapsulation unit and the protective layer.
